(19) United States
(12) Patent Application Publication
(10) Pub. No.: US 2006/0084217 A1
(43) Pub. Date: Apr. 20, 2006

(54) Plasma impurification of a metal gate in a semiconductor fabrication process

(75) Inventors: Tien Ying Luo, Austin, TX (US); Olubunmi O. Adetutu, Austin, TX (US); Hsing H. Tseng, Austin, TX (US)

Correspondence Address: FREESCALE SEMICONDUCTOR, INC., MDTX32/PLO2, 770 W PARMER LANE, AUSTIN, TX, 78729, US

(73) Assignee: Freescale Semiconductor, Inc.

(21) Appl. No.: 10/969,486

(22) Filed: Oct. 20, 2004

(51) Int. Cl. H01L 21/4763

(52) U.S. Cl. 438/199; 438/585; 438/592

(57) ABSTRACT

A semiconductor fabrication includes forming a gate dielectric overlying a semiconductor substrate and depositing a metal gate film overlying the gate dielectric. Following deposition of the metal gate film, nitrogen, carbon, and/or oxygen is introduced into the metal gate film by exposing the metal gate film to a nitrogen, carbon, and/or oxygen bearing plasma. Thereafter, the nitrogenated/oxygenated/carbonated metal gate film is patterned to form a transistor gate electrode. Depositing the metal gate film is preferably done with a low energy process such as atomic layer deposition (ALD) or metal organic chemical vapor deposition (MOCVD) to reduce damage to the underlying gate dielectric. The metal gate film for NMOS devices is preferably a compound of nitrogen and Ti, W, or Ta. A second metal gate film may be used for PMOS devices. This second metal gate film is preferably a compound of oxygen and Ir, Ru, Mo, or Re.

### BACKGROUND

1. Field of Invention

The invention is in the field of semiconductor fabrication processes and, more particularly, fabrication processes employing transistors having metal gates.

2. Background of the Invention

In the field of MOS (metal-oxide-semiconductor) fabrication processes, the gate electrodes of the first MOS transistors were made of metal, namely, aluminum. Aluminum gate transistors had drawbacks, including the inability of aluminum to withstand subsequent high temperature processing. Researchers developed polycrystalline silicon (polysilicon) as an alternative gate electrode material to address the problems presented by aluminum-based transistors. Polysilicon enjoyed a number of advantages over metal gates including better thermal stability and easier integration. Polysilicon has been the most prevalent MOS transistor gate material for at least two decades.

Recently, manufacturers have expressed renewed interest in metal gate transistors, especially in conjunction with high dielectric constant dielectrics, to address issues such as polysilicon depletion and gate leakage associated with conventional silicon oxide dielectrics. In addition, metal gate transistors exhibit a lower resistivity than doped polysilicon. Integrating metal gate electrodes into modern MOS fabrication processes has proven to be challenging. Candidate metals must have work functions near the silicon conduction band for NMOS devices and near the silicon valence band for PMOS devices. However, many thermally stable metals available for CMOS processing have work functions that are mid-bandgap on gate dielectrics and are, therefore, not suitable candidates for NMOS or PMOS gate electrodes. In addition, some candidate metals lack the thermal stability necessary for CMOS processing. Interaction and interdiffusion between the gate dielectric and the metal gate is another issue presented by metal gate technologies. Finally, conventional plasma-assisted techniques for depositing metal gate materials or plasma assisted nitridation of the gate dielectric tend to induce damage in the gate dielectric. It would be desirable to implement a metal gate CMOS fabrication process that addressed these issues.

### BRIEF DESCRIPTION OF THE DRAWINGS

The present invention is illustrated by way of example and not limited by the accompanying figures, in which like references indicate similar elements, and in which:

FIG. 1 is a partial cross-sectional view of a wafer at a selected stage in a semiconductor fabrication process according to the present invention, where gate dielectric films have been formed overlying a substrate;

FIG. 2 depicts processing subsequent to FIG. 1 in which a metal gate film is formed overlying the gate dielectric;

FIG. 3 depicts processing subsequent to FIG. 2 in which the metal gate film is exposed to an impurity bearing plasma;

FIG. 4 depicts processing subsequent to FIG. 3 in which the metal gate film is patterned to form first and second gate electrode structures and first and second transistors are formed;

FIG. 5 depicts alternative processing subsequent to FIG. 3 in which the metal gate film is patterned;

FIG. 6 depicts processing subsequent to FIG. 5 in which a second metal gate film is deposited overlying the wafer;

FIG. 7 depicts processing subsequent to FIG. 6 in which the second metal gate film is exposed to a second impurity bearing plasma;

FIG. 8 depicts processing subsequent to FIG. 7 in which first and second gate electrodes are formed and first and second transistors are formed;

FIG. 9 depicts alternative dual metal gate processing in which the first and second metal gate films are both deposited selectively;

FIG. 10 depicts processing subsequent to FIG. 9 in which first and second transistors are formed.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

Generally speaking, the present invention contemplates a semiconductor fabrication process for incorporating an element such as nitrogen, oxygen, and/or carbon into a metal gate of an MOS transistor. The element is introduced into the metal gate in a manner that minimizes damage to the underlying gate dielectric while still positioning the impurity distribution in close proximity to the metal-gate/dielectric interface where the impurity will have maximum benefit in preventing the migration of unwanted mobile impurities. Nitrogen and carbon are especially effective as a barrier to mobile impurities (e.g., boron) and contaminants (e.g., sodium) while oxygen is useful for improving the thermal stability of some conductive metal oxide gate electrodes, especially metal-oxide gate electrodes including IrO2, RuO2, MoO2, ReO2, as well as other conductive metal oxide materials suitable for use as a PMOS gate electrode.

Turning now to the drawings, FIG. 1 is a partial cross-sectional view of a semiconductor wafer 100 at a selected stage in a semiconductor fabrication process according to one embodiment of the present invention. In the depicted embodiment, wafer 100 is a “bulk” wafer having a substrate 102 that includes a first well region 104 and a second well region 106. The bulk 102 of wafer 100 is preferably composed of single crystal silicon that is doped selectively to achieve desirable doping species and concentrations for first well region 104 and second well region 106. In one implementation, first well region 104 is an n-doped region into which an n-type impurity, such as arsenic or phosphorous, has been introduced while second well region 106 is a p-doped region into which a p-type impurity, such as boron, has been introduced. In other embodiments, wafer 100 is a silicon-on-insulator (SOI) wafer in which the well regions 104 and 106 are included in a top layer that overlies a buried oxide (BOX) layer that overlies a silicon bulk. In other embodiments, wafer 100 may include silicon germanium, gallium arsenide, or the like.

As depicted in FIG. 1, gate dielectric film 110 has been formed overlying first well region 104 and second well region 106 respectively. Gate dielectric 110 may include silicon dioxide, silicon oxynitride (SiₓO_{y}N_{z}), a metal oxide dielectric (MeOx), metal silicates, metal aluminates, metal lanthanate, metal silicate oxynitride, metal oxynitride, silicon nitride, or a combination thereof. Suitable candidates for MeOx gate dielectrics include, as an example, HfO₂. An equivalent oxide thickness (EOT) of gate dielectrics 110 and 120 is preferably less than approximately 25 nm.

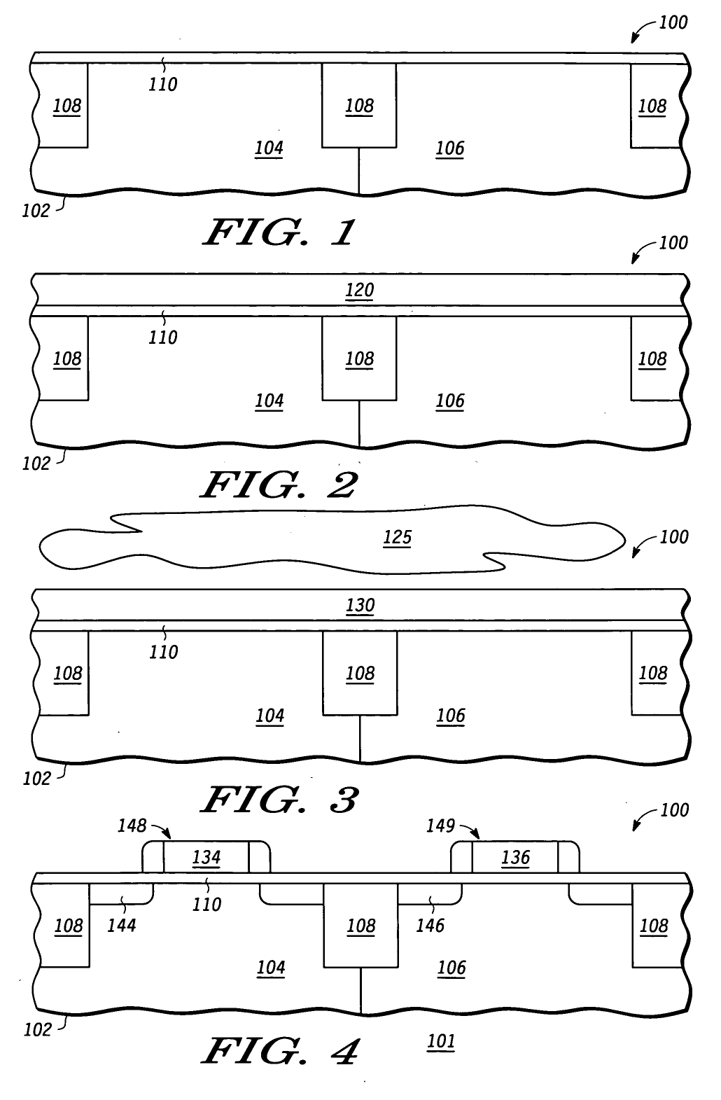

Turning now to FIG. 2, a metal gate film 120 is formed overlying gate dielectric 110. Metal gate film 120 may include a metal such as tungsten, a metal-nitrogen compound, a metal-carbon compound, a conductive metal-oxygen compound or a combination thereof such as in a laminate layer. Metal-nitrogen and metal-carbon compounds suitable for use as a metal gate film 120 include TiN, WN, TaC, TaN, and TaSiN. Conductive metal-oxygen compounds suitable for use as metal gate film 120 include IrO₂, RuO₂, MoO₂, and ReO₂. In one embodiment, metal gate film 120 is deposited using a conventional sputter deposition process. In an alternative embodiment designed to minimize damage to the underlying gate dielectric, deposition of metal gate film 120 is achieved without exposing gate dielectric 110 to highly energized ions and other particles characteristic of ion implantation and plasma-enhanced deposition processes. Formation of metal gate film 120 may be achieved, for example, with a relatively low energy deposition process such as metal organic chemical vapor deposition (MOCVD) or atomic layer deposition (ALD). The use of a low energy metal gate deposition process according to the present invention beneficially preserves the integrity and reliability of the gate dielectric film by reducing dielectric film damage. The thickness of metal gate film 120 is an implementation detail, but is preferably in the range of approximately 1 to 100 nm.

Referring now to FIG. 3, metal gate film 120 (of FIG. 2) is exposed to an impurity-bearing plasma 125 to introduce a barrier-enhancing and work function modifying impurity into the metal gate film. The resulting impurity-modified metal gate film (also referred to herein as “impurified” metal gate film) is identified in FIG. 3 by reference numeral 130. As indicated previously, the impurity introduced into the metal gate film is preferably, nitrogen, oxygen, carbon, or a combination of the these. In one embodiment, metal gate film 120 is plasma nitrided to introduce nitrogen impurities into the first gate electrode. In the preferred embodiment, plasma 125 introduces the corresponding impurity into wafer 100 under conditions that result in a peak concentration of the impurity being positioned in close proximity to the gate dielectric interface (i.e., the interface between impurified metal gate film 130 and gate dielectric 110). Locating the impurity at or close to the gate dielectric interface maximizes the barrier enhancement and work function modulation effects provided by the impurity.

By separating the metal deposition from the impurity incorporation processes, the present invention beneficially achieves a nitrogenated and/or oxygenated gate electrode, without sacrificing reliability resulting from a damaged or stressed gate dielectric film. Whereas, conventional nitrogenated metal gates are achieved with ion implantation or sputter deposition within an ionized chamber, the present invention defers nitrogen incorporation until after the gate dielectric film is physically protected from the environment by the overlying metal gate film. Using a low energy metal gate deposition process followed by a plasma assisted nitrogenation/oxygenation process, the invention results in a more reliable transistor because the incorporated nitrogen modifies the metal gate work function and reduces gate/dielectric interaction and interdiffusion without appreciably damaging the gate dielectric or substantially increasing the cost or complexity of the process.

As depicted in FIG. 4, impurified metal gate film 130 (of FIG. 3) may be patterned to produce gate electrodes 134 and 136 overlying well regions 104 and 106 respectively. Thereafter, source/drain impurity distributions 144 and 146 can be introduced into well regions 104 and 106 respectively to form transistors 148 and 149, all as will be familiar to those skilled in semiconductor fabrication. In a CMOS embodiment, first transistor 148 may be an NMOS transistor while second transistor 149 may be a PMOS transistor. Transistors 148 and 149 are two of many transistors formed in wafer 100 to form an integrated circuit 101. While gate electrodes 134 and 136 are both impurified in the depicted processing sequence, an alternative processing sequence might include a photoresist or hard mask step to selectively impurify either gate electrode 134 or gate electrode 136, but not both, by exposing wafer 100 to plasma 125 after the mask is formed. In still another embodiment, different impurities may be introduced into each gate electrode.

Turning now to FIG. 5 through FIG. 8, a second embodiment of the present invention is depicted to emphasize the use of different gate materials, optimized for different types of transistors, within the context of the present invention. FIG. 5 depicts processing subsequent to the processing depicted in FIG. 3. After fabricating impurified gate film 130 as depicted in FIG. 3, the film is patterned to remove portions of the film overlying first well region 104. In this embodiment, portions of gate film 130 will function as the gate electrode material for transistors formed over second well region 106.

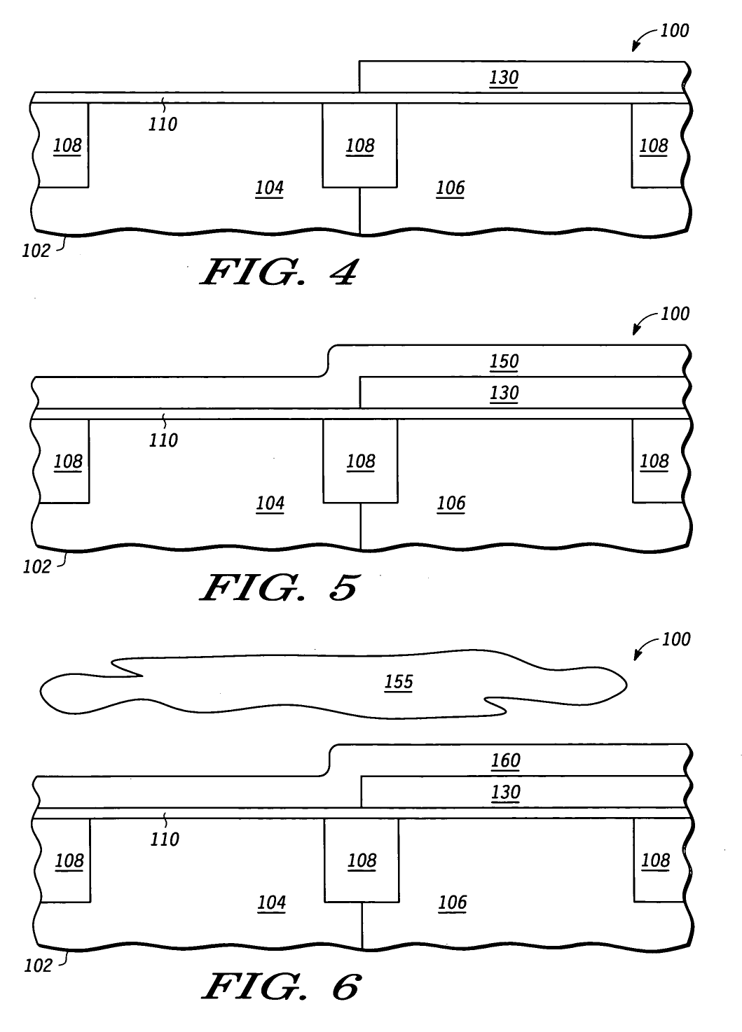

As depicted in FIG. 6, a second gate film 150 is then non-selectively deposited over wafer 100. Second gate film 150 may be deposited in the same manner as metal gate film 120 of FIG. 2 was deposited using sputter deposition or a low energy deposition technique such as MOCVD or ALD. Second metal gate film 150 preferably has a thickness in the range of approximately 1 to 100 nm.

As depicted in FIG. 6 second gate film 150 overlies first gate film 130 above second well region 106, but overlies gate dielectric 110 above first well region 104. Because the gate electrode characteristics of a transistor are dominated by the material in closest proximity to the gate dielectric interface, first gate film 130 is the dominant material for transistors formed over second well region 106 while the second gate film is the dominant material for transistors over first well 104.

For purposes of illustrating this embodiment of the invention, first well region 104 is a PWELL region over which NMOS transistors are formed and second well region 106 is an NWELL region over which PMOS transistors are formed. In this implementation, first metal gate film 130 represents the desired gate metal material for PMOS transistors while the second metal gate film 150 represents the desired gate metal material for NMOS transistors. Suitable candidates for first metal gate film 130 include conductive metal oxide compounds such as IrO2, RuO2, ReO2, and MoO2 while suitable candidates for second metal gate film 150 include W, TiN, WN, TaN, TaC, or TaSiN.

Referring to FIG. 7, second metal gate film 150 (of FIG. 6) is exposed to a second impurity-bearing plasma 155 to introduce an impurity into the film and thereby transform the film into second impurified metal gate film 160. The formation of second metal gate film 160 as shown creates a metal gate stack, comprised of second metal gate film 160 on first metal gate film 130, overlying second well region 106 while second metal gate film 160 alone overlies first well region 104. In other implementations, the gate stack may include other conductive materials and/or non-conductive materials, such as tungsten, silicon, and a hardmask or antireflective coating (of silicon nitride, for example).

Referring now to FIG. 8, first gate electrode 174 and second gate electrode 175 are formed overlying first well region 104 and second well region 106, respectively, using conventional photoresist and lithography processes. In the depicted embodiment, second gate electrode 175 includes a portion of second metal gate film 160 overlying a portion of first metal gate film 130 while first gate electrode 174 includes only a portion of second metal gate film 130. In addition, FIG. 8 illustrates source/drain regions 184 and 186, which have been implanted into well regions 104 and 106, respectively, to form transistors 188 and 189, respectively. Transistors 188 and 189 represent two of many transistors that form an integrated circuit represented by reference numeral 201.

In the implementation under discussion, first transistor 188 is an NMOS transistor while second transistor 189 is a PMOS transistor. In this embodiment, second gate film 160 is preferably comprised of a metal, metal-nitrogen or metal-carbon compound including, as examples, W, TiN, WN, TaN, TaC, TaₓC_{y}N_{z}, or TaSiN. First gate film 130 is preferably comprised of a conductive metal-oxygen compound including, as examples, IrO₂, RuO₂, MoO₂, or ReO₂. The impurity introduced by plasma 155 into second metal gate film 160 is preferably a nitrogen or carbon impurity while the impurity introduced by plasma 125 (FIG. 3) into first metal gate 130 is preferably an oxygen impurity or a combination of an oxygen impurity and a nitrogen impurity. In this embodiment, the nitrogen or carbon impurity in second metal gate 160 beneficially adjusts the metal gate work function for NMOS devices and decreases diffusion between the gate electrode and gate dielectric 110. The oxygen introduced into first metal gate film 130 beneficially improves the thermal stability of at least some of the conductive metal-oxygen compounds and may also modulate the work function of the PMOS gate electrodes. Nitrogen may also be incorporated into first metal gate film 130 to further reduce contaminant mobility.

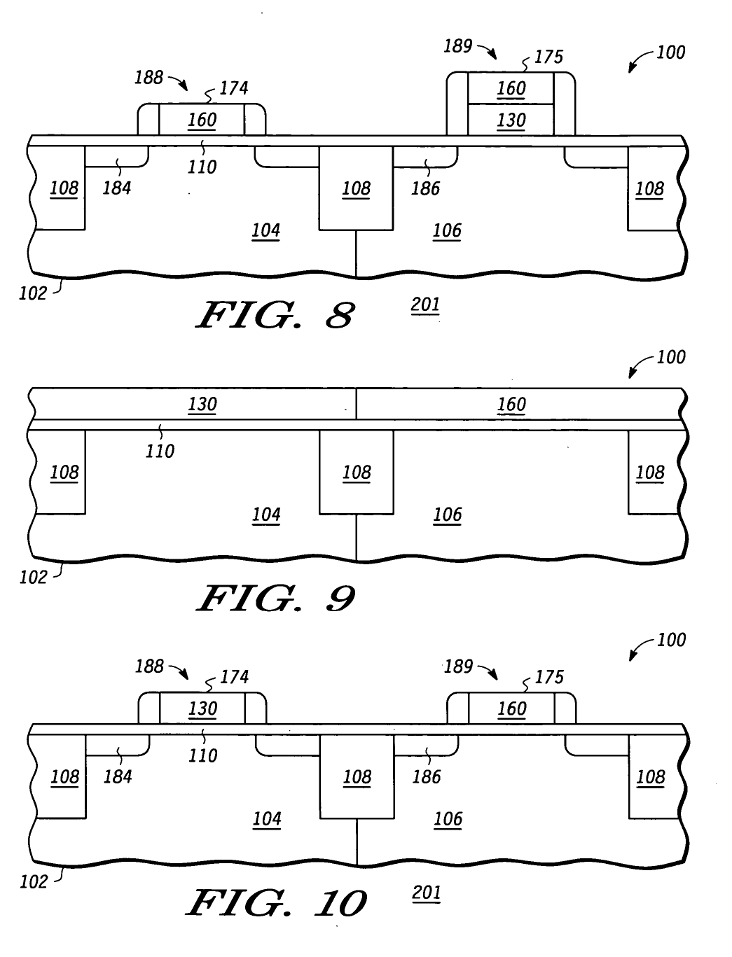

In a variation of the dual metal gate embodiment depicted in FIG. 6 through 8, first and second metal gate films 130 and 160 are formed selectively such that first metal gate film 130 is formed only over first well region 104 and second metal gate film 160 is formed only over second well region 106 as shown in FIG. 9. In this embodiment, both of the metal gate films (130 and 160) are preferably formed with segregated deposition and impurification steps. More specifically, first metal gate film 130 is formed by a first, low energy, metal gate deposition process (e.g., ALD or MOCVD) analogous to the deposition described with respect to FIG. 2, followed by a first impurity plasma process analogous to the plasma step described with respect to FIG. 3. Similarly, second metal gate film 160 is preferably formed by a second, low energy, metal gate deposition step followed by a second impurity plasma step to introduce the second impurity into the second metal gate film.

The second impurity plasma step might be done either selectively (with a mask in place) or non-selectively. The non-selective embodiment might be desirable, for example, to introduce one of the impurities into both of the metal gate films. If it was decided, for example, to introduce an oxygen impurity into the PMOS gate electrode (which is a metal-oxygen compound) and nitrogen into both the NMOS and PMOS gate electrodes, the nitrogen plasma step could be performed non-selectively following the selective deposition of the two metal gate films. An integrated circuit 201 resulting from the wafer as shown in FIG. 9 is depicted in FIG. 10 where a first transistor 188 includes a gate electrode 174 comprised of the first metal gate film 130 only while a second transistor 189 include a gate electrode 175 that includes second metal gate film 160 only.

In the foregoing specification, the invention has been described with reference to specific embodiments. However, one of ordinary skill in the art appreciates that various modifications and changes can be made without departing from the scope of the present invention as set forth in the claims below. For example, although the depicted transistors do not include lightly doped drain (LDD) and/or extension implants, these elements are widely used in short channel devices and may be included in transistors and integrated circuits formed according to the present invention. Similarly, although the depicted integrated circuit employs shallow trench isolation structures, other isolation structures such as conventional LOCOS structures may be used as well. In addition, the specification of certain metal gate compounds and gate dielectric compounds is not intended to exclude other suitable compounds. Furthermore, a skilled artisan should recognize that this method could be used for any gate electrode, such as a gate electrode of a non-volatile memory (NVM) device.

Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A semiconductor fabrication processing, comprising:
forming a gate dielectric overlying a semiconductor substrate;
depositing a metal gate film overlying the gate dielectric;
following said depositing of the metal gate film, introducing an impurity selected from the group consisting of nitrogen, carbon, and oxygen into the metal gate film by exposing the metal gate film to an impurity bearing plasma; and
patterning the metal gate film to form a gate electrode.

2. The process of claim 1, wherein depositing the metal gate film comprises depositing by a process selected from the group consisting of atomic layer deposition (ALD) and metal organic chemical vapor deposition (MOCVD).

3. The process of claim 2, wherein the metal gate film comprises a compound including a first element selected from the group consisting of nitrogen and carbon and a metal element selected from the group consisting of Ti, W, and Ta.

4. The process of claim 3, further comprising, depositing a second metal gate film and thereafter introducing a second impurity into the second metal gate film.

5. The process of claim 4, further comprising, prior to depositing the second metal gate film, patterning the first metal gate film wherein the first metal gate film is present overlying a second well region but is absent over a first well region.

6. The process of claim 5, wherein the second metal gate film comprises a compound of oxygen and a metal selected from the group consisting of Ir, Ru, Mo, and Re.

7. The process of claim 6, wherein the second impurity includes oxygen.

8. The process of claim 1, wherein the gate dielectric is selected from the group consisting of a silicon-oxygen-nitrogen compound, metal-oxygen compound, metal-silicon-oxygen compound, and metal-silicon-oxygen-nitrogen compound.

9. A semiconductor fabrication process, comprising:
depositing a first metal gate film overlying a gate dielectric overlying a semiconductor substrate;
exposing the first metal gate film to a first impurity bearing plasma to introduce a first impurity into the first metal gate film;
patterning the first metal gate film to remove portions of the first metal gate film overlying a first well region of the substrate;
depositing a second metal gate film overlying the gate electrode and the patterned first metal gate film;
exposing the second metal gate film to a second impurity bearing plasma to introduce a second impurity into the second metal gate film; and
patterning the first and second metal gate films to form a first gate electrode overlying the first well region and a second gate electrode overlying the second well region wherein the second gate electrode includes a portion of the first gate film overlying a portion of the second gate film.

10. The method of claim 9, wherein the gate dielectric is selected from the group consisting of a silicon-oxygen-nitrogen compound and a metal oxide, metal silicate, and metal silicon oxynitride.

11. The method of claim 10, wherein depositing the first metal gate film comprises depositing a material selected from the group consisting of IrO2, ReO2, MoO2, and RuO2.

12. The method of claim 11, wherein the first impurity bearing plasma comprises an oxygen bearing plasma.

13. The method of claim 9, wherein the second metal gate film is selected from the group consisting of W, TiN, WN, TaN, and TaSiN.

14. The method of claim 13, wherein the second impurity bearing plasma comprises a plasma selected from the group consisting of a nitrogen bearing plasma and a carbon bearing plasma.

15. The method of claim 14, further comprising forming source/drain regions aligned to the first and second gate electrodes to form first and second transistors.

16. A semiconductor fabrication process, comprising:
depositing a first metal gate film overlying a gate dielectric overlying a substrate by a deposition process selected from the group consisting of sputter deposition, atomic layer deposition (ALD), and metal organic chemical vapor deposition (MOCVD);
plasma nitriding the first metal gate film to introduce nitrogen impurities into the first gate electrode at an interface with the gate dielectric; and
patterning the plasma nitrided first metal gate film to form a first transistor gate electrode.

17. The method of claim 16, wherein the first metal gate film is selected from the group consisting of W, TiN, TaN, and TaSiN.

18. The method of claim 16, further comprising:
depositing a second metal gate film overlying the substrate; and
exposing the second metal gate film to a second impurification plasma to introduce a second impurity into the second metal gate.

19. The method of claim 18, wherein the second metal gate electrode is a conductive metal oxygen electrode.

20. The method of claim 19, wherein the second impurification plasma includes an oxygen bearing ambient.
